(19) United States
(12) Patent Application Publication
(10) Pub. No.: US 2011/0108825 A1
(43) Pub. Date: May 12, 2011

(54) ORGANIC ELECTROLUMINESCENT DEVICE AND ITS PRODUCTION METHOD

(75) Inventor: Yasunori Uetani, Tsukuba-shi (JP)

(73) Assignee: SUMITOMO CHEMICAL COMPANY, LIMITED, Chuo-ku, Tokyo (JP)

(21) Appl. No.: 13/002,743

(22) PCT Filed: Jul. 1, 2009
(86) PCT No.: PCT/JP2009/062399

§ 371 Date: Jan. 5, 2011

(51) Int. Cl. H01L 51/54; H01L 51/56

(52) U.S. Cl. 257/40; 438/46; 257/E51.028

(57) ABSTRACT

An organic electroluminescent device comprising a cathode, an anode formed by an application method, and a light emitting layer disposed between the above-described anode and the above-described cathode.

### CROSS REFERENCE TO RELATED APPLICATION

This application is a National Stage of International Application No. PCT/JP2009/062399 filed Jul. 1, 2009, claiming priority based on Japanese Patent Application No. 2008-179866, filed Jul. 10, 2008, the contents of all of which are incorporated herein by reference in their entirety.

### TECHNICAL FIELD

The present invention relates to an organic electroluminescent device, its production method, a planar light source, an illumination apparatus and a display.

### BACKGROUND ART

Recently, in the electronics field, there are intensified researches and developments of organic functional devices using organic semiconductor materials instead of inorganic semiconductor materials such as silicon and the like. As one of these organic functional devices, an organic electroluminescent device (hereinafter, referred to as organic EL device in some cases) is mentioned. The organic EL device has a constitution including an anode, a light emitting layer and a cathode, and usually, formed on a substrate (Advanced Materials Volume 12, Issue 23, p. 1737-1750 (2000)).

### DISCLOSURE OF THE INVENTION

For example, there is an organic EL device having a constitution in which a cathode, a light emitting layer and an anode are laminated in this order from the substrate side. In the organic EL device having such a constitution, the anode is formed by a vacuum vapor deposition method, a sputtering method and the like, however, these processes are complicated, thus, the productivity of the device is low, resulting in high cost.

The present invention has an object of providing an organic EL device which can be formed by a simple process, and a method of producing the same.

The present invention is an organic electroluminescent device comprising a cathode, an anode formed by an application method, and a light emitting layer disposed between the above-described anode and the above-described cathode.

Further, the present invention is the organic electroluminescent device wherein the above-described anode contains a polyaniline, a polyaniline derivative, or a mixture of a polyaniline and a polyaniline derivative.

Further, the present invention is the organic electroluminescent device wherein the above-described anode contains a polythiophene, a polythiophene derivative, or a mixture of a polythiophene and a polythiophene derivative.

Further, the present invention is the organic electroluminescent device-further comprising a functional layer formed by an application method using a solution having a pH of 5 to 9, the functional layer being disposed between the above-described light emitting layer and the above-described anode and disposed next to them.

Further, the present invention is the organic electroluminescent device wherein the above-described light emitting layer is formed by an application method.

Further, the present invention is a method of producing an organic electroluminescent device having an anode, a cathode and a light emitting layer disposed between the above-described anode and the above-described cathode, comprising

a step of preparing a substrate having a cathode formed thereon,

a step of forming a light emitting layer by an application method, and

a step of forming an anode by an application method,

in this order.

Further, the present invention is a planar light source comprising the above-described organic electroluminescent device.

Further, the present invention is an illumination apparatus comprising the above-described organic electroluminescent device.

Further, the present invention is a display comprising the above-described organic electroluminescent device.

### EMBODIMENTS FOR CARRYING OUT THE INVENTION

The present invention will be described in detail below.

### <Organic EL Device>

The organic EL device of the present invention has a cathode, an anode formed by an application method, and a light emitting layer disposed between the above-described anode and the above-described cathode. The organic EL device is usually formed on a substrate, and for example, constituted by lamination of a cathode, a light emitting layer and an anode in this order from the substrate side.

In the organic EL device, at least one of the anode and the cathode is constituted of a transparent or semi-transparent electrode. A light generated in the light emitting layer is taken out from the transparent or semi-transparent electrode.

For example, an organic EL device having a transparent or semi-transparent substrate and a transparent or semi-transparent cathode, and an opaque anode functions as a so-called bottom emission type device in which a light is taken out from the substrate side.

Since the organic EL device of this embodiment has an anode formed by an application method, the device can be produced at low cost by a simple process, as compared with the case of formation of an anode by a method requiring a complicated process such as a vacuum vapor deposition method, a sputtering method and the like.

### (Substrate)

As described above, the organic EL device is formed usually on a substrate. This substrate is preferably one which does not become deformed in fabricating the organic EL device. Examples of the material of the substrate include glass, plastics, polymer films, silicon and the like. In the case of fabrication of an organic EL device on an opaque substrate, it is preferable that an electrode on the opposite side to an electrode disposed at the substrate side (namely, an electrode situated on the side far from the substrate) is a transparent or semi-transparent, and by using such an electrode, a light can be taken out from the electrode on the opposite side to an electrode disposed at the substrate side.

### (Anode)

The solution used in forming an anode by an application method contains a solvent and a material of the anode.

The anode preferably contains a polymer compound showing an electric conductive property, and preferably is composed of a polymer compound showing substantially an electric conductive property. The polymer compound may contain a dopant. Regarding the electric conductive property of the polymer compound, the electric conductivity thereof is usually 10⁻⁵ to 10⁵ S/cm, preferably 10⁻³ to 10⁵ S/cm.

In the present description, the polymer compound means a compound having a polystyrene-equivalent number average molecular weight of 500 or more.

The anode constituent material includes a polyaniline and derivatives thereof, a polythiophene and derivatives thereof, a polypyrrole and derivatives thereof, and the like. As the dopant, known dopants can be used, and examples thereof include organic sulfonic acids such as polystyrenesulfonic acid, dodecylbenzenesulfonic acid and the like, and Lewis acids such as PF₅, AsF₅, SbF₅ and the like. The polymer compound showing an electric conductive property may also be a self doping type polymer compound in which a dopant is directly bonded to a polymer compound.

The anode preferably has a constitution containing a polyaniline and/or a polyaniline derivative, and preferably is composed substantially of a polyaniline and/or a polyaniline derivative. (The polyaniline and/or polyaniline derivative may contain a dopant.) Examples of the polyaniline and derivatives thereof include compounds containing one or more structures among several structures represented by the following formulae.

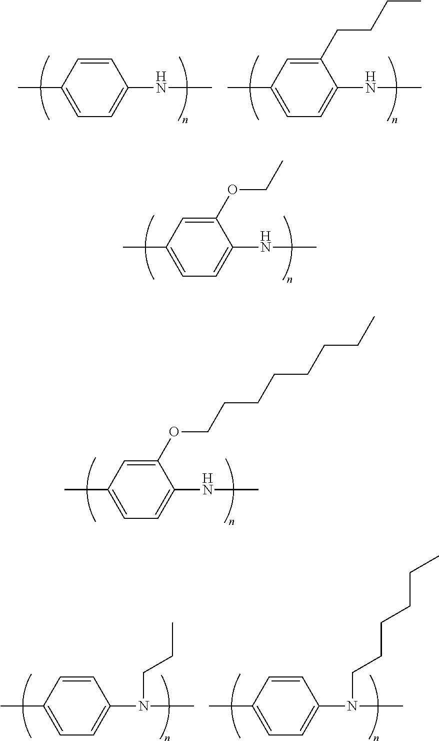

(wherein, n represents 1 or an integer of 2 or more.).

A polyaniline, a polyaniline derivative or a mixture of a polyaniline and a polyaniline derivative is suitably used as a solute of an application liquid to be used in an application method, because of a readily soluble property in solvents described later. These compounds have a high electric conductive property and are used suitably as electrode materials. Further, these compounds have a HOMO energy of about 5.0 eV, the difference from the HOMO energy of usual organic light emitting layers being as low as about 1 eV or less, thus, holes can be injected efficiently into a light emitting layer, and because of reason, these compounds can be used suitably as anode materials. Since some of these compounds are soluble in aqueous solvents such as water, alcohols and the like, if, for example, a layer on which an anode is formed by application (hereinafter, a layer having a surface on which a given layer is formed by application is referred to as “lower layer” for the given layer) shows solubility in an organic solvent and shows poor solubility in an aqueous solvent, then, an anode can be formed while suppressing a damage on the lower layer, in forming an anode by application using an application liquid using an aqueous solvent. Particularly, as the lower layer on which an anode is formed by application, a layer soluble in an organic solvent is often used, thus, by using such anode materials, an organic EL device of high reliability can be formed easily.

The anode preferably has a constitution containing a polythiophene and/or a polythiophene derivative, and preferably is composed substantially of a polythiophene and/or a polythiophene derivative. (The polythiophene and/or polythiophene derivative may contain a dopant.) Examples of the polythiophene and derivatives thereof include compounds containing one or more structures among several structures represented by the following formulae.

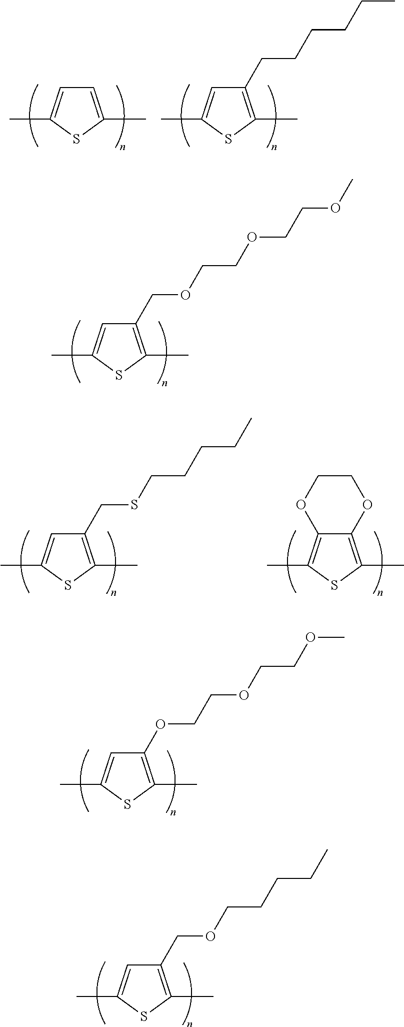

(wherein, n represents 1 or an integer of 2 or more.).

The polythiophene and/or polythiophene derivative can be used suitably as an electrode because of an excellent electric conductive property and excellent stability, and can be suitably used also as a transparent electrode because of high transparency.

Examples of the polypyrrole and/or polypyrrole derivatives include compounds having one or more structures among several structures represented by the following formulae. (The polypyrrole and/or polypyrrole derivative may contain a dopant.).

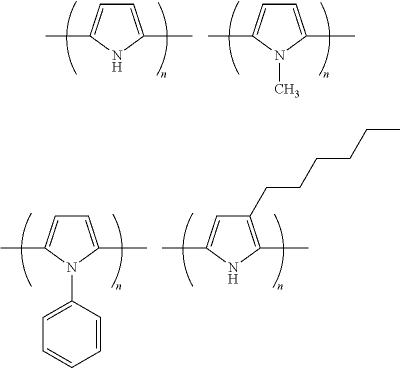

(wherein, n represents 1 or an integer of 2 or more.).

An anode may be formed by an application method using not only solutions containing the above-described organic materials but also using a metal ink, a metal paste, a low melting point metal in melted state and the like.

Between an anode and a light emitting layer, a given layer is sometimes provided, aiming at improvement in device properties such as light emission efficiency, device life and the like.

### (Functional Layer)

Between an anode and a light emitting layer, a functional layer is preferably disposed next to the light emitting layer and the anode, and it is preferable that this functional layer is formed by an application method using a solution having a pH of 5 to 9.

In the present description, pH is a value measured using a pH test paper.

The functional layer functions as what is called a hole transporting layer and/or a hole injection layer. The functions of the functional layer include a function of enhancing injection efficiency of holes into an anode, a function of preventing injection of electrons from a light emitting layer, a function of enhancing hole transportability, a function of preventing a solution used in forming an anode by an application method from eroding a light emitting layer, a function of suppressing deterioration of a light emitting layer, and the like.

The functional layer is preferably composed of a polymer compound, and more preferably composed of a polymer compound having a high electric conductive property. Regarding the electric conductive property of the polymer compound having a high electric conductive property, the polymer compound has an electric conductivity of 10⁻⁵ to 10⁵ S/cm, preferably 10⁻³ to 10⁴ S/cm.

The constituent material of the functional layer includes a polymer compound containing a thiophene-diyl group, a polymer compound containing an aniline-diyl group, a polymer compound containing a pyrrole-diyl group, and the like. The solution used in applying and forming a functional layer contains these functional layer constituent materials and a solvent. When the functional layer disposed next to a light emitting layer is, for example, formed by application using a strongly acidic solution, there is a possibility of imparting a damage to the light emitting layer, however, since the functional layer is formed by an application method using a solution having a pH of 5 to 9, an organic EL device of high reliability can be fabricated. Further, in the case of use of a strongly acidic solution, there is a possibility of injuring an application apparatus and the like, however, since the functional layer is formed by an application method using a solution having a pH of 5 to 9, it is not necessary to particularly use an application apparatus and the like which are durable to the acidic solution, thus, an organic EL device can be fabricated easily, and a cost required in fabricating a device can be suppressed.

These polymer compounds may have an acid group such as a sulfonic acid group and the like, and examples thereof include poly(thiophenes) and poly(anilines) having an acid group such as a sulfonic acid group and the like as the substituent. The poly(thiophenes) and poly(anilines) may further have a substituent, and examples thereof include halogen atoms, alkyl groups having 1 to 20 carbon atoms, alkoxy groups having 1 to 20 carbon atoms, aryl groups having 6 to 60 carbon atoms, and groups represented by the formula (I):

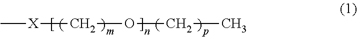

(wherein, n represents an integer of 1 to 4, m represents an integer of 1 to 6 and p represents an integer of 0 to 5, respectively. X represents an oxygen atom or a direct bond),
and alkoxy groups and groups represented by the formula (I) are preferably carried from the standpoint of solubility in water and alcohol solvents.

In the present invention, the application liquid and the solution include also dispersion systems such as an emulsion, a suspension and the like.

By disposing a functional layer next to an anode and a light emitting layer, the close adherence of the anode can be enhanced and the injection efficiency of holes from the anode into the light emitting layer can be enhanced. By providing such a functional group, an organic EL device of high reliability can be realized.

The functional layer is preferably constituted of a material showing high wettability to a solution used in forming an anode by application. Specifically, it is preferable to provide a functional layer composed of a member showing higher wettability to a solution used in forming an anode by application than the wettability of a light emitting layer. In formation of an anode by forming an anode on such a functional layer by application, the solution successfully wets and spreads on the surface of the functional layer, and an anode of uniform thickness can be formed easily.

The thickness of the functional layer is usually 1 nm to 1000 nm, preferably 2 nm to 500 nm, more preferably 5 nm to 200 nm.

### (Light Emitting Layer)

The light emitting layer is usually formed predominantly of an organic material emitting fluorescence and/or phosphorescence, or formed of the organic material and a dopant for aiding the same. The light emitting layer is preferably formed by an application method. The light emitting layer preferably contains a polymer compound, and one polymer compound may be contained singly or two or more polymer compounds may be contained in combination, and it is further preferable that the light emitting layer has a constitution containing a conjugated polymer compound. For enhancing the charge transportability of the above-described light emitting layer, an electron transportable compound and/or a hole transportable compound can also be mixed in the above-described light emitting layer. Examples of the light emitting materials constituting the light emitting layer include dye-based materials, metal complex-based materials, polymer-based materials and dopant materials described below.

### Dye-Based Material

Examples of the dye-based material include cyclopendamine derivatives, tetraphenylbutadiene derivatives, triphenylamine derivatives, oxadiazole derivatives, pyrazoloquinoline derivatives, distyrylbenzene derivatives, distyrylarylene derivatives, pyrrole derivatives, thiophene ring compounds, pyridine ring compounds, perinone derivatives, perylene derivatives, oligothiophene derivatives, an oxadiazol dimmer, a pyrazoline dimmer, quinacridone derivatives, coumarin derivatives, and the like.

### Metal Complex-Based Material

Examples of the metal complex-based material include metal complexes having Al, Zn, Be and the like, or a rare earth metal such as Tb, Eu, Dy and the like as the central metal and having oxadiazole, thiadiazole, phenyl pyridine, phenyl benzoimidzole, quinoline structure and the like as the ligand, and examples thereof include metal complexes showing light emission from the triplet excited state such as an iridium complex, a platinum complex and the like, and an aluminum quinolinol complex, a benzoquinolinol beryllium complex, a benzooxazolyl zinc complex, a benzothiazol zinc complex, an azomethyl zinc complex, a porphyline zinc complex, an europium complex and the like.

### Polymer-Based Material

The polymer-based material includes a polyparaphenylene vinylene derivative, a polythiophene derivative, a polyparaphenylene derivative, a polysilane derivative, a polyacetylene derivative, a polyfluolene derivative, a polyvinyl carbazol derivative, a polymer of the above-described dye-based material or metal complex-based light emitting material, and the like.

Among the above-described light emitting materials, materials showing blue light emission include a distyryl arylene derivative, an oxadiazol derivative, and a polymer thereof, a polyvinyl carbazol derivative, poloparaphenylene derivative, a polyfluolene derivative and the like. In particular, polymer materials such as a polyvinyl carbazol derivative, a polyparaphenylene derivative, a polyfluolene derivative and the like are preferable.

Materials showing green light emission include a quinacrydone derivative, a coumarine derivative, and a polymer thereof, a polyparaphenylene vinylene derivative, a polyfluolene derivative and the like. In particular, polymer materials such as a polyparaphenylene vinylene derivative, a polyfluolene derivative and the like are preferable.

Materials showing red light emission include a coumarine derivative, a thiophene ring compound, and a polymer thereof, a polyparaphenylene vinylene derivative, a polythiophene derivative, a polyfluolene derivative and the like. In particular, polymer materials such as a polyparaphenylene vinylene derivative, a polythiophene derivative, a polyfluolene derivative and the like are preferable.

### Dopant Material

Examples of the dopant material include a perylene derivative, a coumarine derivative, a rubrene derivative, a quinacridone derivative, a squalium derivative, a porphyline derivative, a styryl-based dye, a tetracene derivative, a pyrazoline derivative, decacyclene, phenoxazone and the like. The thickness of such a light emitting layer is usually about 2 nm to 200 nm.

The thickness of the light emitting layer is usually 1 nm to 100 μm, preferably 2 nm to 1000 nm, more preferably 5 nm to 500 nm, further preferably 20 nm to 200 nm.

### (Cathode)

The cathode is disposed on the substrate side against an anode. In an organic EL device of bottom emission type from which a light is taken out from the substrate side through a cathode as described above, the cathode is preferably constituted of a transparent or semi-transparent electrode. As the transparent or semi-transparent electrode, an electrically conductive metal oxide film, a semi-transparent metal film, an organic substance-containing transparent electric conductive film and the like are used. Specifically used are films made of indium oxide, zinc oxide, tin oxide, indium tin oxide (abbreviation: ITO), indium zinc oxide (abbreviation: IZO), gold, platinum, silver, copper, aluminum, polyaniline and derivatives thereof, and polythiophene and derivatives thereof, and the like, and of them, films made of ITO, IZO and tin oxide are suitably used.

In an organic EL device of so-called top emission type from which a light is taken out from the anode side which is opposite to a substrate, the cathode may not be transparent or semi-transparent, and may also be opaque. As such a cathode, a material showing a small work function, manifesting easy injection of electrons into a light emitting layer and having high electric conductivity is preferable. For example, alkali metals, alkaline earth metals, transition metals, group XIII metals and the like can be used. As such cathode materials, for example, metals such as lithium, sodium, potassium, rubidium, cesium, beryllium, magnesium, calcium, strontium, barium, aluminum, scandium, vanadium, zinc, yttrium, indium, cerium, samarium, europium, terbium, ytterbium and the like, alloys composed of two or more of them, or alloys composed of at least one of them and at least one of gold, silver, platinum, copper, manganese, titanium, cobalt, nickel, tungsten and tin, and graphite or graphite intercalation compounds and the like are used.

The thickness of the cathode is usually 1 nm to 1 mm, preferably 10 nm to 100 μm, more preferably 20 nm to 10 μm.

Between a cathode and a light emitting layer, a given layer is further disposed in some cases for the purpose of improving device properties such as light emission efficiency, device life and the like, and for example, an electron transporting layer having a function of transporting electrons, an electron injection layer having a function of improving electron injection efficiency, a buffer layer having a function of promoting electron injection and surface flattening, a hole blocking layer of blocking movement of holes, and the like, are disposed. This buffer layer is disposed next to a cathode. Between an anode and a light emitting layer, a hole injection layer having a function of improving hole injection efficiency, a hole transporting layer having a function of transporting hole, an electron blocking layer having a function of blocking movement of electrons, and the like, are disposed in some cases, in addition to the above-described functional layers.

Examples of possible layer constitutions of the organic EL device are shown below.

a) anode/light emitting layer/cathode

b) anode/hole injection layer/light emitting layer/cathode

c) anode/hole injection layer/light emitting layer/electron injection layer/cathode

d) anode/hole injection layer/light emitting layer/electron transporting layer/cathode

e) anode/hole injection layer/light emitting layer/electron transporting layer/electron injection layer/cathode

f) anode/hole transporting layer/light emitting layer/cathode

g) anode/hole transporting layer/light emitting layer/electron injection layer/cathode

h) anode/hole transporting layer/light emitting layer/electron transporting layer/cathode

i) anode/hole transporting layer/light emitting layer/electron transporting layer/electron injection layer/cathode

j) anode/hole injection layer/hole transporting layer/light emitting layer/cathode

k) anode/hole injection layer/hole transporting layer/light emitting layer/electron injection layer/cathode

l) anode/hole injection layer/hole transporting layer/light emitting layer/electron transporting layer/cathode

m) anode/hole injection layer/hole transporting layer/light emitting layer/electron transporting layer/electron injection layer/cathode

n) anode/light emitting layer/electron injection layer/cathode

o) anode/light emitting layer/electron transporting layer/cathode

p) anode/light emitting layer/electron transporting layer/electron injection layer/cathode

(here, the mark “/” means adjacent lamination of layers sandwiching the mark “/”. The same shall apply hereinafter.)

The organic EL device of the present embodiment may have two or more light emitting layers, and the organic EL device having two light emitting layers includes those having the following layer constitution q).

q) anode/charge injection layer/hole transporting layer/light emitting layer/electron transporting layer/charge injection layer/charge generating layer/charge injection layer/hole transporting layer/light emitting layer/electron transporting layer/charge injection layer/cathode

The organic EL device having three or more light emitting layers includes specifically those having a layer constitution containing (charge generating layer/charge injection layer/hole transporting layer/light emitting layer/electron transporting layer/charge injection layer) as one repeating unit and containing the above-described two or more repeating units represented by the following formula r).

r) anode/charge injection layer/hole transporting layer/light emitting layer/electron transporting layer/charge injection layer/(the repeating unit)/(the repeating unit)/ . . . /cathode

In the above-described layer constitutions r) and q), layers other than the anode, the electrode, the cathode and the light emitting layer can be deleted if necessary.

In the case of disposal of either a hole injection layer or a hole transporting layer between a light emitting layer and an anode, as in b) to i), among the above-described constitutions, it is preferable that one layer disposed between a light emitting layer and an anode is constituted of the above-described functional layer. Even in the case of formation of two or more layers between a light emitting layer and an anode, one of these layers may be constituted of the above-described functional layer.

The hole injection layer, the hole transporting layer, the electron injection layer, the electron transporting layer and the buffer layer will be described below.

### (Hole Injection Layer)

In the case of disposal of a layer different from the above-described functional layer as the hole injection layer, materials constituting the hole injection layer include oxides such as vanadium oxide, molybdenum oxide, ruthenium oxide, aluminum oxide and the like, phenyl amines, starburst type amines, phthalocyanines, amorphous carbon, polyaniline, polythiophene derivatives and the like.

### (Hole Transporting Layer)

In the case of disposal of a layer different from the above-described functional layer as the hole transporting layer, materials constituting the hole transporting layer include polyvinyl carbazole or derivatives thereof, polysilane or derivatives thereof, polysiloxane derivatives having an aromatic amine on the side chain or main chain, pyrazoline derivatives, arylamine derivatives, stilbene derivatives, triphenyldiamine derivatives, polyaniline or derivatives thereof, polythiophene or derivatives thereof, polyarylamine or derivatives thereof, polypyrrole or derivatives thereof, poly(p-phenylenevinylene) or derivatives thereof, poly(2,5-thienylenevinylene) or derivatives thereof, and the like.

### (Electron Transporting Layer)

As the electron transporting material constituting the electron transporting layer, known materials can be used, and these materials include oxadiazole derivatives, anthraquinodimethane or derivatives thereof, benzoquinone or derivatives thereof, naphthoquinone or derivatives thereof, anthraquinone or derivatives thereof, tetracyanoanthraquinodimethane or derivatives thereof, fluorenone derivatives, diphenyldicyanoethylene or derivatives thereof, diphenoquinone derivatives, metal complexes of 8-hydroxyquinoline or derivatives thereof, polyquinoline or derivatives thereof, polyquinoxaline or derivatives thereof, polyfluorene or derivatives thereof, and the like.

### (Electron Injection Layer)

As the material constituting the electron injection layer, optimum materials are appropriately selected depending on the kind of a light emitting layer, and these materials include alkali metals, alkaline earth metals, alloys containing one or more materials among alkali metals and alkaline earth metals, oxides of alkali metals or alkaline earth metals, halides, carbonates, a mixture of these substances, and the like.

### (Buffer Layer)

As the material constituting the buffer layer, fluorides of alkali metals such as lithium fluoride and the like, halides of alkaline earth metals, oxides thereof, and the like, can be used. It is also possible to form a charge transporting layer using fine particles of an inorganic semiconductor such as titanium oxide and the like.

### <Production Method of Organic EL Device>

The method of producing an organic EL device of the present invention contains a step of preparing a substrate having a cathode formed thereon, a step of forming a light emitting layer by an application method and a step of forming an anode by an application method, in this order.

### (Step of Preparing Substrate Having Cathode Formed Thereon)

First, the above-described substrate is prepared. Next, the above-described cathode material is subjected to film formation by a vacuum vapor deposition method, a sputtering method, an ion plating method, a plating method or the like, to form a cathode. It is also possible to form a cathode by an application method using a solution containing an organic material such as a polyaniline and derivatives thereof, a polythiophene and derivatives thereof and the like, a metal ink, a metal paste, a low melting point metal in melted state, or the like. The substrate having a cathode formed thereon as described above may also be purchased and used.

### (Layer Between Cathode and Light Emitting Layer)

Between a cathode and a light emitting layer, a buffer layer, an electron injection layer, an electron transporting layer and the like are disposed if necessary, as described above. These layers are preferably formed by an application using a solution containing a solvent and a material of the layer. A buffer layer, en electron injection layer, an electron transporting layer, a hole blocking layer and the like may be used also by using a vapor deposition method and the like.

The solvent includes chlorine-based solvents such as chloroform, methylene chloride, dichloroethane and the like, ether solvents such as tetrahydrofuran and the like, aromatic hydrocarbon solvents such as toluene, xylene and the like, ketone solvents such as acetone, methyl ethyl ketone and the like, ester solvents such as ethyl acetate, butyl acetate, ethyl cellosolve acetate and the like, and water.

The application method includes a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an inkjet print method and the like.

For example, it is possible to form an electron transporting layer by forming a film on a cathode by an application method using a titania solution, and further drying the film.

### (Step of Forming Light Emitting Layer)

The organic film used in a light emitting layer can be formed by an application method using a solution containing a solvent and the above-described light emitting layer constituent material, and for example, can be formed by an application method using a solution containing a solvent and a conjugated polymer compound.

Examples of the solvent include hydrocarbon solvents such as toluene, xylene, mesitylene, tetralin, decalin, bicyclohexyl, n-butylbenzene, s-butylbenzene, t-butylbenzene and the like, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like, halogenated unsaturated, hydrocarbon solvents such as chlorobenzene, dichlorobenzene, trichlorobenzene and the like, ether solvents such as tetrahydrofuran, tetrahydropyran and the like, etc.

The solution used in the present invention may contain two or more solvents, and may contain two or more of the above-exemplified solvents.

The method for applying a solution containing the above-described light emitting layer constituent material includes application methods such as a spin coat method, a casting method, a micro gravure coat method, a gravure coat method, a bar coat method, a roll coat method, a wire bar coat method, a dip coat method, a spray coat method, a screen printing method, a flexo printing method, an offset printing method, an inkjet printing method, a dispenser printing method, a nozzle coat method, a capillary coat method and the like, and of them, a spin coat method, a flexo printing method, an inkjet printing method and a dispenser printing method are preferable.

### (Layer Between Light Emitting Layer and Anode)

Between a light emitting layer and an anode, a functional layer which functions as a hole transporting layer and/or a hole injection layer, and the like are disposed if necessary, as described above. The functional layer is preferably formed by an application method using a solution containing a solvent and a material of the functional layer. In addition to the functional layer, a hole transporting layer, a hole injection layer, an electron blocking layer and the like may be formed if necessary.

### (Step of Forming Functional Layer)

The functional layer is formed by an application method using a solution having a pH of 5 to 9, after formation of a light emitting layer. This solution contains a solvent and a functional layer constituent material. In the case of disposal of the functional layer next to a light emitting layer, the functional layer is formed by applying the above-described solution having a pH of 5 to 9 on the surface of a light emitting layer. It is preferable to form the functional layer using a solution giving a small damage on a lower layer below a light emitting layer on which the solution is applied, and specifically, it is preferable to form a functional layer using a solution poorly dissolving a lower layer below a light emitting layer. For example, if a solution used in forming an anode is applied directly on a light emitting layer, it is preferable to form a functional layer using a solution giving a smaller damage on a light emitting layer than the damage given on a light emitting layer by this solution, and specifically, it is preferable to form a functional layer using a solution more poorly dissolving a light emitting layer than the solution used in forming an anode. By forming the functional layer as described above, the functional layer functions as a protective layer in forming an anode by application, thus, an organic EL device of high reliability can be formed.

The solution used in forming the functional layer by application contains a solvent and the above-described functional layer constituent material. The solvent of the above-described solution includes water, alcohols and the like, and examples of the alcohol include methanol, ethanol, isopropanol, butanol, ethylene glycol, propylene glycol, butoxyethanol, methoxybutanol and the like. The solution used in the present invention may contain two or more solvents, and may also contain two or more of the above-exemplified solvents.

In the case of disposal of a hole transporting layer, a hole injection layer and the like in addition to the functional layer, these layers are preferably formed by an application method using a solution containing a solvent and a material of the layer to be disposed.

### (Step of Forming Anode)

The anode is formed by an application method. Specifically, the anode is formed by applying a solution containing a solvent and the above-described anode constituent material on the surface of a lower layer. Examples of the solvent of the solution used in forming the anode include hydrocarbon solvents such as toluene, xylene, mesitylene, tetralin, decalin, bicyclohexyl, n-butylbenzene, s-butylbenzene, t-butylbenzene and the like, halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, bromocyclohexane and the like, halogenated unsaturated hydrocarbon solvents such as chlorobenzene, dichlorobenzene, trichlorobenzene and the like, ether solvents such as tetrahydrofuran, tetrahydropyran and the like; water, alcohols and the like. Examples of the alcohol include methanol, ethanol, isopropanol, butanol, ethylene glycol, propylene glycol, butoxyethanol, methoxybutanol and the like. The solution used in the present invention may contain two or more solvents, and may also contain two or more of the above-exemplified solvents.

The anode is preferably formed by application using a solution poorly dissolving a lower layer. For example, if the lower layer is soluble in an organic solvent and in-soluble in an aqueous solvent such as water, alcohols and the like, then, it is preferable to form an anode using an aqueous solvent. For example, in the case of formation of an anode on a light emitting layer, it is preferable to form an anode using an aqueous solvent since the light emitting layer is usually easily soluble in an organic solvent, and by forming an anode using such a solution, an organic EL device of high reliability can be produced.

In this embodiment, it is preferable to form residual constituent components excluding a cathode among components constituting an organic EL device by an application method. By forming components by an application method as a simple process as described above, an organic EL device can be formed simply, and productivity is improved and the cost of device production can be decreased. It is further preferable to form all constituent components constituting an organic EL device also including a cathode by an application method. By forming all components by an application as a simple process as described above, an organic EL device can be formed simply, and productivity is improved and the cost of device production can be decreased.

The organic EL device explained above can be suitably used in curved and plat illumination apparatuses, for example, a planar light source used as a light source of a scanner, and a display. An apparatus equipped with an organic EL device which can be produced by the simple process as described above can be produced at low cost by the same simple process as for the organic EL device.

The display equipped with an organic EL device includes segment displays, dot matrix displays and the like. The dot matrix display includes an active matrix display, a passive matrix display and the like. An organic EL device is used as a light emitting device constituting a picture element in an active matrix display and a passive matrix display. An organic EL device is used as a light emitting device constituting a segment in a segment display, and used as a backlight in a liquid crystal display.

### EXAMPLES

Examples for illustrating the present invention further in detail will be shown below, but the present invention is not limited to them.

### Example 1

### Fabrication of Organic EL Device, and Evaluation Thereof

On a glass substrate carrying an ITO film having a thickness of 150 nm as a cathode formed by a sputtering method, a solution prepared by diluting a nano titania solution manufactured by Shokubai Kasei Co. (PASOL HDW-10R #BF18) in 2-fold weight of isopropanol was applied by spin coating. Next, in atmospheric air, the film formed by application was dried at 120° C. for 10 minutes. The thickness of the resultant titanium oxide layer was about 20 nm.

Next, a 0.1 wt % isopropanol solution of cesium carbonate was applied by spin coating. The thickness of the resultant layer is thin, and guessed to be 10 nm or less.

Next, a 1.5 wt % xylene solution of a green light emitting organic material (manufactured by Sumation Co., Ltd., Lumation GP1300) was applied by spin coating, to obtain a light emitting layer (film thickness: about 100 nm). Thereafter, an HIL691 solution (manufactured by Plextronics, Inc, trade name: Plexcore HIL691) was applied by spin coating, to obtain a functional layer (film thickness: about 100 nm). The value of pH of the HIL691 solution was measured by a pH-test paper (manufactured by Advantec Toyo Kaisha, Ltd., trade name “UNIVERSAL”, model number “07011030”), to find pH7. Thereafter, a polyaniline solution (ORMECON D1033W (water solvent) manufactured by Nissan Chemical Industries, Ltd.) was applied, then, dried in vacuum for 60 minutes, to form an anode composed of the polyaniline. The thickness of the polyaniline was about 130 nm. The anode composed of the polyaniline was transparent. The shape of the resultant organic EL device was a rectangle of 2 mm×6 mm.

### Example 2

### Fabrication of Organic EL Device, and Evaluation Thereof

On a glass substrate carrying an ITO film having a thickness of 150 nm as a cathode formed by a sputtering method, a solution prepared by diluting a nano titania solution manufactured by Shokubai Kasei Co. (PASOL HDW-10R #BF18) in 2-fold weight of isopropanol was applied by spin coating. Next, in atmospheric air, the film formed by application was dried at 120° C. for 10 minutes. The thickness of the resultant titanium oxide layer'was about 20 nm.

Next, a 0.1 wt % isopropanol solution of cesium carbonate was applied by spin coating. The thickness of the resultant layer is thin, and guessed to be 10 nm or less.

Next, a 1.5 wt % xylene solution of a green light emitting organic material (manufactured by Sumation Co., Ltd., Lumation GP1300) was applied by spin coating, to obtain a light emitting layer (film thickness: about 100 nm). Thereafter, a polyaniline solution (ORMECON D1033W (water solvent) manufactured by Nissan Chemical Industries, Ltd.) was applied, then, dried in vacuum for 60 minutes, to form an anode composed of the polyaniline. The thickness of the polyaniline was about 130 nm. The anode composed of the polyaniline was transparent. The shape of the resultant organic EL device was a rectangle of 2 mm×6 mm.

### Example 3

### Fabrication of Organic EL Device, and Evaluation Thereof

On a glass substrate carrying an ITO film having a thickness of 150 nm as a cathode formed by a sputtering method, a solution prepared by diluting a nano titania solution manufactured by Shokubai Kasei Co. (PASOL HDW-10R #BF18) in 2-fold weight of isopropanol was applied by spin coating. Next, in atmospheric air, the film formed by application was dried at 120° C. for 10 minutes. The thickness of the resultant titanium oxide layer was about 20 nm.

Next, a 0.1 wt % isopropanol solution of cesium carbonate was applied by spin coating. The thickness of the resultant layer is thin, and guessed to be 10 nm or less.

Next, a 1.5 wt % xylene solution of a green light emitting organic material (manufactured by Sumation Co., Ltd., Lumation GP1300) was applied by spin coating, to obtain a light emitting layer (film thickness: about 100 nm). Thereafter, an OC1200 solution (manufactured by Plextronics, trade name: Plexcore OC1200, purchased from Sigma Aldrich) was applied by spin coating, to obtain a hole transporting layer (film thickness: about 50 nm). The value of pH of the OC1200 solution was measured by a pH-test paper (manufactured by Advantec Toyo Kaisha, Ltd., trade name “UNIVERSAL”, model number “07011030”), to find pH7. Thereafter, a polyaniline solution (ORMECON D1033W (water solvent) manufactured by Nissan Chemical Industries, Ltd.) was applied, then, dried in vacuum for 60 minutes, to form an anode composed of the polyaniline. The thickness of the polyaniline was about 130 nm. The anode composed of the polyaniline was transparent. The shape of the resultant organic EL device was a rectangle of 2 mm×6 mm.

Plexcore OC1200 is a solution of the following sulfonated polythiophene in 2% ethylene glycol monobutyl ether/water=3:2.

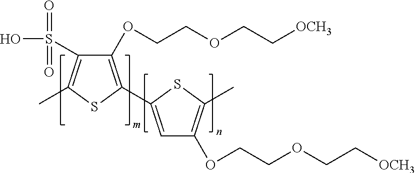

### —Evaluation—

The voltage applied to an organic EL device was gradually changed, and the front face luminance of EL light emission emitted from the organic EL device was measured. In the organic EL device fabricated in the example, a light is emitted from both the cathode side and the anode side since both anode and cathode are transparent, however, in this evaluation, the front face luminance of a light emitted from the cathode side was measured. As a result, in Example 1, green light emission (light emission peak wavelength: 535 nm) was obtained showing a luminance of 1170 cd/m² in applying a voltage of 20 V. In Example 2, green light emission (light emission peak wavelength: 535 nm) was obtained showing a luminance of 1440 cd/m² in applying a voltage of 20 V. In Example 3, green light emission (light emission peak wavelength: 535 nm) was obtained showing a luminance of 1050 cd/m² in applying a voltage of 20 V. As is understood from the above-described descriptions, good light emission was confirmed also in an organic EL device obtained by forming residual constituent components excluding a cathode among all constituent components by an application method.

### INDUSTRIAL APPLICABILITY

The organic EL device can be produced at low cost by a simple process since an anode is formed by an application method. A planar light source, an illumination apparatus and a display equipped with such an organic EL device can be produced at low cost by the same simple process as for the organic EL device.

1. An organic electroluminescent device comprising a cathode, an anode formed by an application method, and a light emitting layer disposed between said anode and said cathode.

2. The organic electroluminescent device according to claim 1 wherein said anode contains a polyaniline, a polyaniline derivative, or a mixture of a polyaniline and a polyaniline derivative.

3. The organic electroluminescent device according to claim 1 wherein said anode contains a polythiophene, a polythiophene derivative, or a mixture of a polythiophene and a polythiophene derivative.

4. The organic electroluminescent device according to claim 1 further comprising a functional layer formed by an application method using a solution having a pH of 5 to 9, the functional layer being disposed between said light emitting layer and said anode and disposed next to them.

5. The organic electroluminescent device according to claim 1 wherein said light emitting layer is formed by an application method.

6. A method of producing an organic electroluminescent device having an anode, a cathode and a light emitting layer disposed between said anode and said cathode, comprising
a step of preparing a substrate having a cathode formed thereon,
a step of forming a light emitting layer by an application method, and
a step of forming an anode by an application method,
in this order.

7. A planar light source comprising the organic electroluminescent device according to claim 1.

8. An illumination apparatus comprising the organic electroluminescent device according to claim 1.

9. A display comprising the organic electroluminescent device according to claim 1.
